(19) United States
(12) Patent Application Publication
(10) Pub. No.: US 2003/0142486 A1
(43) Pub. Date: Jul. 31, 2003

(54) Electromagnetic wave shielding sheet

(75) Inventors: Fumihiro Arakawa, Shinjuku-Ku (JP); Eiji Ohishi, Shinjuku-Ku (JP); Yasuhiko Ishii, Shinjuku-Ku (JP)

Correspondence Address: PARKHURST & WENDEL, L.L.P., 1421 PRINCE STREET, SUITE 210, ALEXANDRIA, VA, 22314-2805, US

(73) Assignee: Dai Nippon Printing Co., Ltd., Shinjuku-Ku (JP)

(21) Appl. No.: 10/320,742

(22) Filed: Dec. 17, 2002

(30) Foreign Application Priority Data
Dec. 19, 2001 (JP) 2001-386537

(51) Int. Cl. H05K 9/00

(52) U.S. Cl. 361/818

(57) ABSTRACT

The present invention discloses a sheet for electromagnetic wave shielding, comprising a laminate of at least a transparent substrate film and an electromagnetic wave shielding layer. The electromagnetic wave shielding layer is formed of a meshy metal foil with densely arranged openings and being transparent. A protective film is stacked separably on the laminate either in its surface of transparent substrate film side or in its surface of electromagnetic wave shielding layer side.

### BACKGROUND OF THE INVENTION

1. Field of the Invention

The present invention relates to an electromagnetic wave shielding sheet which, when used, is placed on the viewing side of an electromagnetic device such as a display and can shield electromagnetic waves.

2. Background Art

Electromagnetic waves generated from electromagnetic devices can adversely affect other electromagnetic devices or human body and animals. To avoid the adverse effect, various electromagnetic wave shielding means have hitherto been developed and used. In particular, since plasma displays (hereinafter referred to as “PDPs”) generate electromagnetic waves with frequencies of 30 to 130 MHz which often adversely affect computers or peripheral devices of computers, minimizing the leakage of electromagnetic waves generated from PDPs to the outside of the PDPs is required.

Conventional means for electromagnetic wave shielding include a method wherein the electromagnetic device is covered with a case made of a high electrically conductive material and a method wherein the electromagnetic device is covered with an electrically conductive net. These methods, however, sometimes sacrifice see-through properties of the electromagnetic device and thus are not suitable for devices where viewing is necessary. Electromagnetic wave shielding means composed of a transparent indium tin oxide (hereinafter referred to as “ITO”) film provided on a transparent film has also been developed. The ITO film, however, has a high level of see-through properties, but on the other hand, the electrical conductivity is so low that the electromagnetic wave shielding capability is poor. As a result, this means can be used only in devices which generate no significant amount of electromagnetic waves.

On the other hand, a sheet having a combination of electromagnetic wave shielding capability with see-through properties has been developed. This sheet is produced by etching a metal foil stacked onto a film to densely form openings and, thus, to render the metal foil meshy. Further, in this type of sheet, an improved sheet has been provided in which the thickness of the metal foil and the dimension of the mesh have been made proper, the capability of shielding the same level of electromagnetic waves as the level of the electromagnetic waves generated from PDPs has been imparted, and the visibility of the display screen has been improved.

The sheet composed of a meshy metal foil stacked on a transparent film and produced by the etching, however, is fabricated so that the metal foil is in the form of lines with a very small width around 10 μm. Therefore, breaking of lines sometimes occurs, for example, upon contact. Further, since etching of the metal foil involves the step of coating a resist, the step of pattern exposure, the step of etching, the step of removing the resist, etc., the surface of the transparent film remote from the metal foil is often contaminated or attacked, for example, upon contact with the etching liquid, or is attacked upon contact with an alkaline liquid for resist separation at the time of the removal of the resist.

### SUMMARY OF THE INVENTION

The present inventor has now found that, in an electromagnetic wave shielding sheet produced by stacking a metal foil onto a transparent film substrate and etching the metal foil to densely form openings and thus to render the metal foil meshy, the covering of the electromagnetic wave shielding sheet on its metal side or its film substrate side with a protective film, which is different from the electromagnetic wave shielding sheet, is advantageous in that lines even with very small width fabricated from the metal foil are less likely to be broken, and, at the same time, even upon treatments such as etching of the metal foil, the transparent substrate film and the like are neither contaminated nor attacked. The present invention has been made based on such finding.

Accordingly, an object of the present invention is to provide an electromagnetic wave shielding sheet in which lines even with very small width fabricated from the metal foil are less likely to be broken, and, at the same time, even upon treatments such as etching of the metal foil, the transparent substrate film and the like are neither contaminated nor attacked.

According to one aspect of the present invention, there is provided a sheet for electromagnetic wave shielding, comprising

a laminate of at least a transparent substrate film and an electromagnetic wave shielding layer,

said electromagnetic wave shielding layer being formed of a meshy metal foil with densely arranged openings and being transparent,

a protective film being stacked separably on the laminate either in its surface of transparent substrate film side or in its surface of electromagnetic wave shielding layer side.

### BRIEF DESCRIPTION OF THE DRAWINGS

FIG. 1 is a diagram showing an embodiment of an electromagnetic wave shielding sheet;

FIG. 2 is a diagram showing a position where a protective film is provided;

FIG. 3 is a diagram showing a production process of a laminate with a meshy metal foil stacked thereon; and

FIG. 4 is a diagram showing an embodiment of an electromagnetic wave shielding panel.

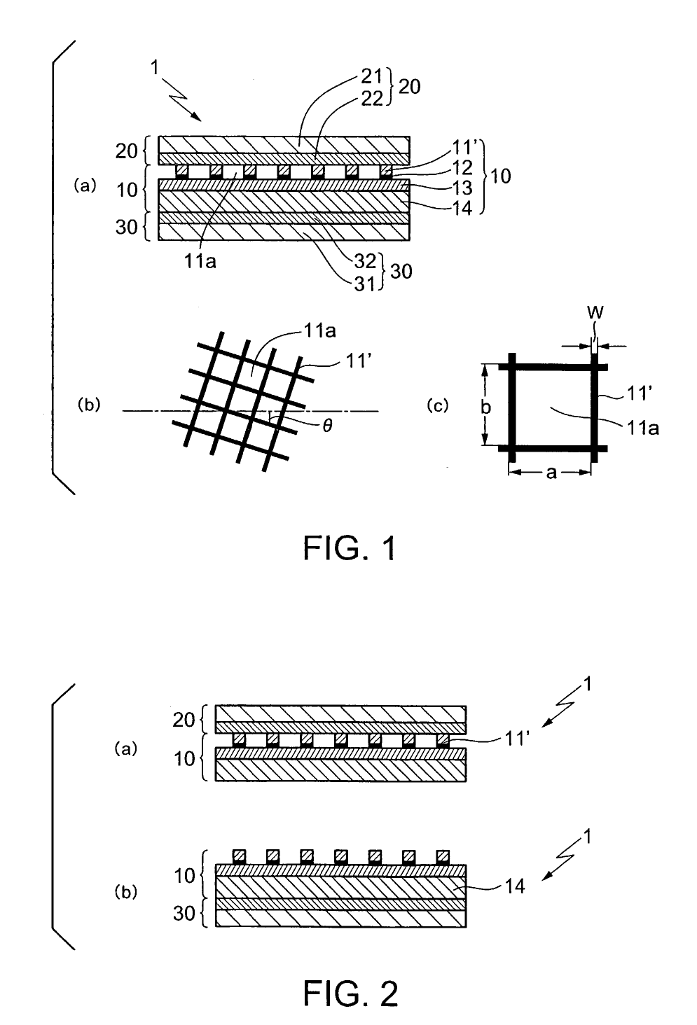

### DESCRIPTION OF REFERENCE CHARACTERS IN FIGS. 1 TO 4

1: electromagnetic wave shielding sheet, 10: laminate, 11: metal foil (11′: meshy metal foil), 12: blackened layer, 13: adhesive layer, 14: transparent substrate film, 20 and 30: protective film, 21 and 31: film, and 22 and 32: adhesive layer.

### DETAILED DESCRIPTION OF THE INVENTION

### Embodiments of the Invention

According to a first embodiment of the present invention, there is provided a sheet for electromagnetic wave shielding, comprising a laminate of at least a transparent substrate film and a transparent electromagnetic wave shielding layer formed of a meshy metal foil with densely arranged openings, a protective film being stacked separably on the laminate either in its surface of transparent substrate film side or in its surface of electromagnetic wave shielding layer side.

According to a second embodiment of the present invention, there is provided a sheet for electromagnetic wave shielding, comprising a laminate of at least a transparent substrate film and a transparent electromagnetic wave shielding layer formed of a meshy metal foil with densely arranged openings, a protective film being stacked separably on the laminate both in its surface of transparent substrate film side and in its surface of electromagnetic wave shielding layer side.

The first and second embodiments of the present invention can provide an electromagnetic wave shielding sheet which can prevent breaking of mesh and, in each of steps such as etching, can avoid the occurrence of contamination and attack.

According to a third embodiment of the present invention, there is provided a sheet for electromagnetic wave shielding wherein, in the first or second embodiment of the present invention, the peel strength between the protective film and the laminate is 5 mN/25 mm-width to 5 N/25 mm-width. The third embodiment can provide an electromagnetic wave shielding sheet which, in addition to the above effects, has an advantage that there is no fear of causing unintentional separation of the protective film during handling or accidental contact and requires no excessive force for intentionally separating the protective film.

### Electromagnetic Wave Shielding Sheet

The present invention will be described in detail with reference to FIG. 1. FIG. 1 is a cross-sectional view of an electromagnetic wave shielding sheet according to a preferred embodiment of the present invention. As shown in FIG. 1(a), in an electromagnetic wave shielding sheet 1 in this preferred embodiment, a meshy metal foil 11′ is stacked on a transparent substrate film 14 through an adhesive layer 13 to constitute a laminate 10. A protective film is provided on both sides of the laminate 10. Specifically, a protective film 20 is stacked on one side of the laminate 10, and a protective film 30 is stacked on the other side of the laminate 10. A blackened layer 12 is stacked on the metal foil 11′ in its transparent substrate film 14 side.

As shown in FIG. 1(b), in the electromagnetic wave shielding sheet 1, the metal foil 11′ is such that openings 11a are densely arranged to form a mesh. As shown in FIG. 1(c), in the opening 11a, the width w of the lines is small and 5 μm to 20 μm. Pitches a, b in the vertical and horizontal directions may be the same or different and each may be about 50 μm to 500 μm. In this case, the percentage opening per unit area is preferably about 90% to 95%. Further, the lines may be properly inclined at angle θ to the horizontal direction (horizontal direction at the time of viewing). The “meshy” may be a lattice form as shown in FIG. 1(b). The shape of the opening 11a is not limited to this only and may be a shape other than quadrilateral, for example, hexagonal honeycomb, circle, or ellipse.

Unlike the above embodiment, the protective film may not be always provided on both sides of the electromagnetic wave shielding sheet 1. For example, as shown in FIG. 2(a), a protective film 20 may be provided only on the meshy metal foil 11′ in the laminate 10 and may not be provided on the transparent substrate film 14 side. Alternatively, as shown in FIG. 2(b), a protective film 30 is provided only on the transparent substrate film 14 side of the laminate 10 and may not be provided on the metal foil 11′. In FIGS. 2 and 1, like parts are identified with the same reference numerals.

### Laminate Structure of Electromagnetic Wave Shielding Sheet and Production Process Thereof

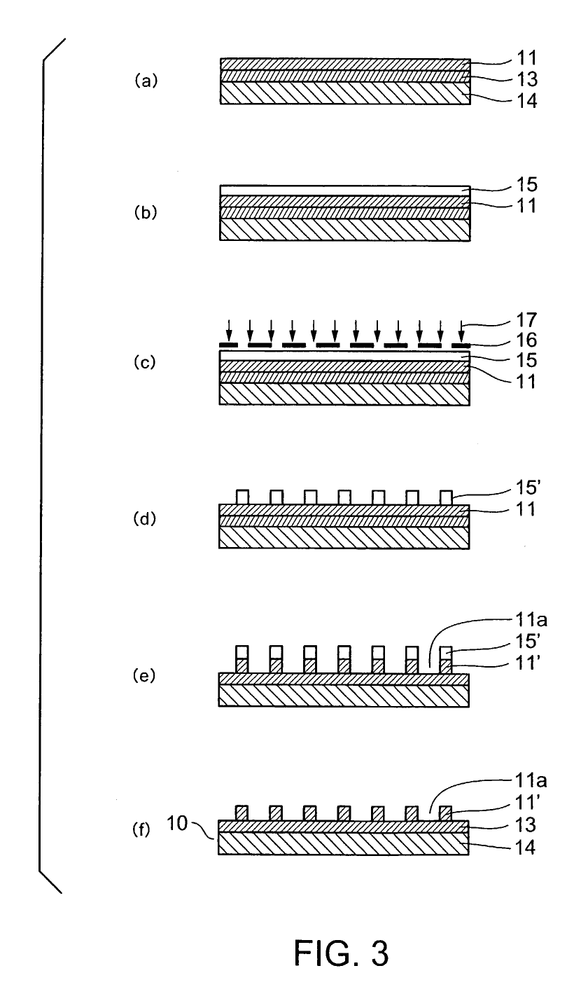

The layer construction of the laminate of at least a transparent substrate film 14 and a transparent electromagnetic wave shielding layer formed of a meshy metal foil 11′ with densely arranged openings in the electromagnetic wave shielding sheet 1 according to the present invention and a production process of the laminate will be described with reference to FIGS. 3(a) to (f).

As shown in FIG. 3(a), a laminate of a metal foil 11 stacked onto a transparent substrate film 14 through an adhesive layer 13 is provided.

The transparent substrate film 14 may be a film of acrylic resin, polycarbonate resin, polypropylene resin, polyethylene resin, polystyrene resin, polyester resin, cellulosic resin, polysulfone resin, polyvinyl chloride resin or the like. A film of polyester resin such as polyethylene terephthalate resin is preferably used because of its excellent mechanical strength and high transparency. The thickness of the transparent substrate film 14 is not particularly limited. From the viewpoints of mechanical strength and increased bending resistance, however, the thickness of the transparent substrate film 14 is preferably about 50 μm to 200 μm. A larger thickness may be adopted. When the electromagnetic wave shielding sheet 1 is used in the state of being stacked onto another transparent substrate, however, the thickness of the transparent substrate film 14 may not be always above the above defined thickness range. Preferably, corona discharge treatment of or the provision of an easy-adhesion layer on one or both sides of the transparent substrate film 14 is if necessary adopted.

The metal foil 11 is not particularly limited and may be a foil of a metal, such as copper, iron, nickel, or chromium, or an alloy of two or more of these metals, or an alloy composed mainly of one or more of these metals. The use of a copper foil, however, is preferred because of its high electromagnetic wave shielding capability, easy etching, and easy handling. The copper foil may be a foil of rolled copper or electrolytic copper. The use of electrolytic copper is preferred from the viewpoints of easiness of the production of a foil having a small thickness of not more than 10 μm, even thickness and good adhesion to a blackened layer at the time of plating for blackened layer formation. In each of FIGS. 3(a) to (f), although the blackened layer (12) is not shown, the blackened layer 12 may be provided.

The thickness of the metal foil 11 is preferably 1 μm to 100 μm, more preferably 5 μm to 20 μm. When the thickness of the metal foil 11 is in this range, the electromagnetic wave shielding capability is satisfactory. Further, in this case, since good side etching can be realized, openings can easily be formed with predetermined accuracy.

In the metal foil 11, a blackened layer (12) formed by blackening treatment may be provided on the transparent substrate film 14 side. This construction can offer rust preventive effect and, at the same time, can impart antireflection properties. The blackened layer can be formed, for example, by Co—Cu alloy plating and can prevent reflection from the surface of the metal foil 11. Further, the surface of the metal foil 11 may be subjected to chromate treatment for rust preventive purposes. In the chromate treatment, a rust preventive film may be formed by dipping the metal foil 11 in a solution composed mainly of chromic acid or a bichromate and drying the coating. One or both sides of the metal foil 11 may be subjected to chromate treatment. Alternatively, for example, a commercially available copper foil subjected to chromate treatment may be utilized. When the metal foil 11 used is not a previously blackened metal foil, the metal foil may be blackened in the next step. The blackened layer may be formed by forming a photosensitive resin layer 15, which can function as a resist layer, using a black colored composition and, after the completion of etching, allowing the resist layer to remain unremoved. Alternatively, the blackened layer may be formed by plating which can provide a black film.

When a film of heat-fusible resin, such as highly heat-fusible ethylene-vinyl acetate copolymer resin or ionomer resin, either alone or as a laminate onto another resin film, is used as the transparent substrate film 14, the transparent substrate film 14 and the metal foil 11 may be stacked on top of each other without the provision of any adhesive layer. In general, however, the lamination is carried out, for example, by a dry lamination method using an adhesive layer. Adhesives usable for constituting the adhesive layer include acrylic resins, polyester resins, polyurethane resins, polyvinyl alcohol resins, vinyl chloride-vinyl acetate copolymer resins, and ethylene-vinyl acetate copolymer resins. Examples of other adhesives usable herein include heat-curable resins and ionizing radation-curable resins, for example, ultraviolet-curable resins and electron beam-curable resins.

As shown in FIG. 3(b), a photosensitive resin layer 15, which can be brought into a resist layer in a subsequent etching process, is then stacked onto the metal foil 11 in the laminate thus obtained. The photosensitive resin layer 15 may be either positive-working or negative-working.

As shown in FIG. 3(c), an ionizing radiation, such as ultraviolet light 17, is applied through a pattern 16 onto the stacked photosensitive resin layer 15. Alternatively, the exposure may be carried out by a method involving electron beam scanning without the use of the pattern 16. That is, the exposure may be carried out by any method so far as pattern-wise exposure is possible. When the photosensitive resin layer 15 is negative-working, the exposed portion is cured and is insolubilized in a developing solution, while the unexposed portion is soluble in the developing solution. On the other hand, when the photosensitive resin layer 15 is positive-working, the exposed portion is decomposed and consequently is solubilized in the developing solution.

The exposed photosensitive resin layer 15 is developed with a developing solution. In this case, since the layer is divided into soluble portions and insoluble portions by the above exposure, the soluble portions are dissolved and removed by allowing a developing solution, which has been predetermined depending upon the type of the photosensitive resin, to act on the exposed photosensitive resin layer 15. As shown in FIG. 3(d), when the photosensitive resin layer 15 is negative-working, the cured patterned photosensitive resin layer 15′ remains unremoved on the metal foil 11.

Etching is then carried out utilizing the cured photosensitive resin layer 15′, which has remained unremoved on the metal foil 11, as a resist. The etching may be either dry etching or wet etching. The etching is carried out until the metal foil 11 in its portions not covered with the resist is removed by etching to form openings. When openings having a predetermined shape have been formed, the etching is completed. Thus, as shown in FIG. 3(e), a meshy metal foil 11′ with densely arranged openings 11a is provided.

When the cured photosensitive resin layer 15′ as the resist stays on the meshy metal foil 11′ at the point of time of the completion of etching, the resist is removed with a resist removing liquid to expose a meshy metal foil 11′ with densely arranged openings 11a as shown in FIG. 3(f). Thus, a laminate 10 is provided wherein a meshy metal foil 11′ has been stacked onto a transparent substrate film 14 through an adhesive layer 13.

The laminate of at least a transparent substrate film 14 and a meshy metal foil 11′ with densely arranged openings can be produced as described above. If necessary, for example, the step of degreasing or cleaning the surface of the metal foil 11 to be fabricated or the step of washing away a resist removing liquid after the removal of the residual resist may be provided.

In the electromagnetic wave shielding sheet 1 according to the present invention, the purpose of stacking the protective film 20 onto the upper surface side of the laminate 10, that is, on the metal foil 11′ side, wherein a meshy metal foil 11′ optionally provided with a blackened layer (12) has been stacked onto a transparent substrate film 14 through an adhesive layer 13, is to protect small-width lines of the metal foil constituting the meshy metal foil 11′ against breaking, for example, upon contact.

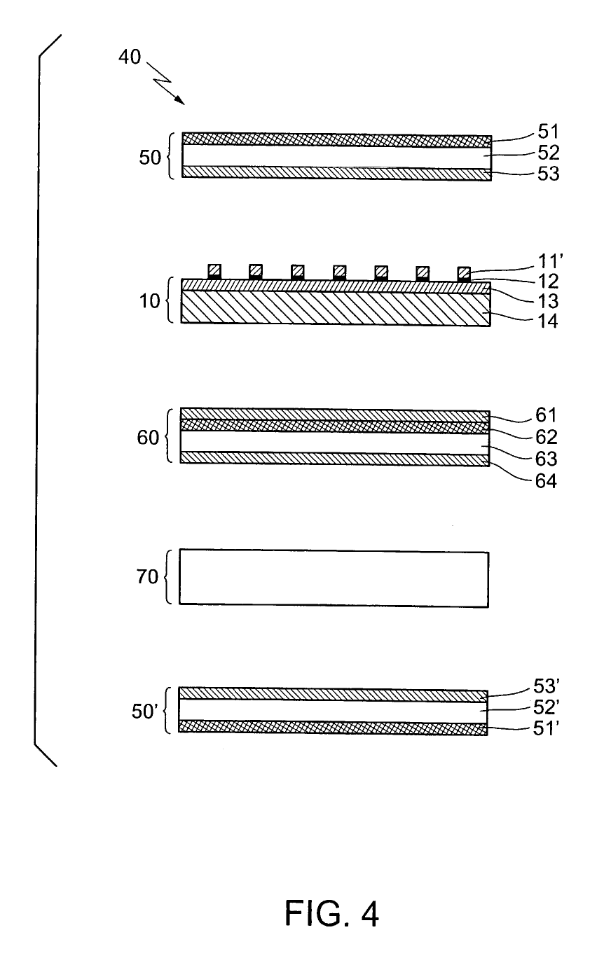

The use of the electromagnetic wave shielding sheet 1 will be described with reference to FIG. 4. Specifically, in use of the electromagnetic wave shielding sheet 1, the laminate 10 is stacked onto a substrate, for example, through an infrared cut filter layer. Further, sheets having outermost surface reinforcement effect, reflection prevention-imparting effect, antifouling property-imparting effect, etc. are stacked respectively on the upper and lower surfaces of the laminate. In the above further lamination of the laminate, the protective film 20 should be stripped off. For this reason, the protective film 20 is preferably stacked separably on the metal foil 11′ side.

The peel strength between the protective film 20 and the metal foil 11′ in the laminate is preferably 5 mN/25 mm-width to 5 N/25 mm-width, more preferably 10 mN/25 mm-width to 100 mN/25 mm-width. When the peel strength is in the above defined range, the desired protective film 20 can be easily intentionally stripped off, and, at the same time, unintentional separation of the meshy metal foil 11′ from the transparent substrate film 14 (or the adhesive layer 13) can be prevented.

In the electromagnetic wave shielding sheet 1 according to the present invention, the purpose of stacking the protective film 30 onto the lower surface side, that is, the transparent substrate film 14 side, of the laminate 10, wherein a meshy metal foil 11′ optionally provided with a blackened layer (12) has been stacked onto a transparent substrate film 14 through an adhesive layer 13, is to protect the lower surface of the transparent substrate film against damaging during handling or upon accidental contact, or is to prevent the contamination or attack of the exposed surface of the transparent substrate film 14 in steps wherein a resist layer is provided on the metal foil 11 followed by etching, particularly at the time of etching.

As with the protective film 20, this protective film 30 should be stripped off at the time of further lamination of the laminate 10. Therefore, the protective film 30 is preferably stacked separably on the transparent substrate film 14 side. As with the peel strength of the protective film 20, the peel strength of the protective film 30 is preferably 5 mN/25 mm-width to 5 N/25 mm-width, more preferably 10 mN/25 mm-width to 100 mN/25 mm-width.

The protective film 30 stacked onto the transparent substrate film 14 side preferably can withstand etching conditions, for example, is not attacked by an etching liquid of about 50° C. during dipping in the etching liquid for several min, particularly an alkaline component in the etching liquid. In the case of the dry etching, the protective film 30 preferably can withstand a temperature of about 100° C. In dipping (dip coating) of the laminate 10 at the time of the lamination of the photosensitive resin layer 15, the coating liquid is deposited also on the opposite surface of the laminate 10. Therefore, the protective film 30 preferably has adhesion to the photosensitive resin to avoid such an unfavorable phenomenon that, in the step of etching or the like, the photosensitive resin is separated and drifts in the etching liquid. When an etching liquid is used, the protective film 30 preferably has a resistance property high enough to resist contamination with an etching liquid containing iron chloride, copper chloride or the like, or a resistance property high enough to resist, for example, attack by or contamination with a resist removing liquid such as an alkaline liquid.

Preferred films usable for constituting the protective film 30 include resin films, for example, films of polyolefin resins such as polyethylene resins and polypropylene resins, polyester resins such as polyethylene terephthalate resins, polycarbonate resins, or acrylic resins. Further, from the above viewpoint, preferably, the protective film 30 at least on its surface constituting the outermost surface in the state of application onto the laminate 10 is subjected to corona discharge treatment, or is stacked with an easy-adhesion layer.

The pressure-sensitive adhesive for constituting the protective film 30 may be an acrylic ester, rubber, or silicone pressure-sensitive adhesive.

The material for the film for the protective film 30 and the material for the pressure-sensitive adhesive as such are applicable to the protective film 20 applied to the metal foil 11′ side. That is, the protective film 20 and the protective film 30 may be the same or different.

### Electromagnetic Wave Shielding Panel

According to the present invention, there is provided an electromagnetic wave shielding panel. The electromagnetic wave shielding panel will be described in detail with reference to FIG. 4. FIG. 4 is a schematic diagram of an electromagnetic wave shielding panel which has been configured using the electromagnetic wave shielding sheet 1 according to the present invention. The upper side of FIG. 4 is the viewing side, and the lower side is the rear side. The electromagnetic wave shielding panel is placed on the viewing side of a display such as PDP (not shown). In an electromagnetic wave shielding panel 40, a viewing side (=front face) film 50 is stacked through the adhesive layer 13 onto the metal foil 11′ side of the laminate 10, wherein the meshy metal foil 11′ has been stacked onto the transparent substrate film 14 (that is, on the viewing side) (the metal foil 11′ on its adhesive layer 13 side being optionally provided with the blackened layer 12). The viewing-side film 50 comprises a pressure-sensitive adhesive layer 53, a film 52, and a multilayer 51 stacked in that order from the laminate 10 side. The multilayer 51 includes a hardcoat, an antireflection layer, and an antifouling layer stacked in that order.

A near-infrared absorption film 60, a glass substrate 70, and a rear side (=backside) film 50′ are stacked in that order on the transparent substrate film 14 side of the laminate 10. The near-infrared absorption film 60 comprises a pressure-sensitive adhesive layer 61, a near-infrared absorption layer 62, a film 63, and a pressure-sensitive adhesive layer 64 stacked in that order from the laminate 10 side. The glass substrate 70 is provided to ensure the mechanical strength, self-supporting properties, or flatness of the whole electromagnetic wave shielding panel 40. The backside (=rear side) film 50′ comprises a pressure-sensitive adhesive layer 53′, a film 52′, and a multilayer 51′ stacked in that order from the glass substrate 70 side. The multilayer 51′ includes a hardcoat, an antireflection layer, and an antifouling layer stacked in that order. In this embodiment, the backside film 50′ is the same as the viewing-side film 50.

The electromagnetic wave shielding panel 40 described above with reference to FIG. 4 is mere an embodiment and preferably comprises the above laminates stacked on top of one another. If necessary, however, alterations and modifications are possible. For example, any of the laminates or layers may be omitted, or a laminate having a combination of functions of layers may be provided and used.

### EXAMPLES

### Example 1

A transparent polyethylene terephthalate resin (=PET) film having a width of 700 mm and a thickness of 100 μm (a product of Toyobo Co., Ltd., stock number: A 4300) and a copper foil with one side thereof being blackened, which had a width of 700 mm and a thickness of 10 μm (a product of Furukawa Circuit Foil Co., Ltd., stock number: BW-S), were provided. The PET film and the copper foil were continuously stacked onto top of each other by dry lamination using a two-component-curable polyurethane resin adhesive (a product of Takeda Chemical Industries, Ltd.; a mixture of Takelac A 310 (main component)/Takenate A 10 (curing agent)/ethyl acetate=12/1/21 (mass ratio)) so that the blackened surface faced inward. A protective film A (a product of Panac Kogyo K. K., stock number: HT-25) composed of a PET film and an acrylic pressure-sensitive adhesive layer stacked on the PET film and having a total thickness of 28 μm, in which the surface of the PET film remote from the pressure-sensitive adhesive layer had been subjected to corona discharge treatment, was then laminated by means of a laminator roller onto the surface of the PET film remote from the copper foil to prepare a laminate having a construction of protective film A/PET film/adhesive layer/copper foil.

Casein was coated onto the copper foil side of the laminate thus obtained, and the coating was dried to form a photosensitive resin layer. A mask with a pattern formed thereon was put on top of the photosensitive resin layer, and the laminate was then subjected to contact exposure to ultraviolet light. After the exposure, development with water and curing treatment were carried out, followed by baking at 100° C. to form a resist pattern. The pattern of the mask was such that a mesh pattern of pitch: 300 μm and line width: 10 μm was formed in an area of 600 mm×800 mm.

A ferric chloride solution (Baume degree: 42, temperature: 30° C.) was sprayed onto the laminate, with a resist pattern formed thereon, from its resist pattern side to perform etching. Thereafter, the laminate was washed with water, and the resist was then separated with an alkaline solution. After the separation, washing and drying were carried out to prepare a laminate having a construction of protective film A/PET film/adhesive layer/copper mesh.

### Example 2

A protective film B (a product of SUN A. KAKEN CO., LTD., stock number: Sanitect Y-26F) composed of a polyethylene film and an acrylic pressure-sensitive adhesive layer stacked on the polyethylene film and having a total thickness of 65 μm was laminated by means of a laminator roller onto the surface of the laminate in its copper mesh side to prepare a laminate having a construction of protective film A/PET film/adhesive layer/copper mesh/protective film B.

### Comparative Example 1

The procedure of Example 1 was repeated, except that the protective film A in Example 1 was changed to a protective film A1 (a product of Hitachi Chemical Co., Ltd., stock number: Hitalex CL-5125) composed of a polyethylene film and a modified rubber pressure-sensitive adhesive layer stacked on the polyethylene film and having a total thickness of 60 μm.

### Comparative Example 2

The procedure of Example 1 was repeated, except that the protective film A in Example 1 was changed to a protective film A2 (a product of SUN A. KAKEN CO., LTD., stock number: Sanitect PAC-2) which was a polyethylene coextruded self-adhesive film and had a total thickness of 10 μm.

### Comparative Example 3

The procedure of Example 1 was repeated, except that the protective film B in Example 1 was changed to a protective film B1 (a product of Hitachi Chemical Co., Ltd., stock number: Hitalex CL-5150) composed of a polyethylene film and a modified rubber pressure-sensitive adhesive layer stacked on the polyethylene film and having a total thickness of 60 μm.

### Comparative Example 4

The procedure of Example 1 was repeated, except that the protective film B in Example 1 was changed to a protective film B2 (a product of SUN A. KAKEN CO., LTD., stock number: Sanitect PAC-2) which was a polyethylene coextruded self-adhesive film and had a total thickness of 10 μm.

### Evaluation Test

The electromagnetic wave shielding sheets with a protective film prepared in Examples 1 and 2 and Comparative Examples 1 to 4 were evaluated, and the results are shown in “Table 1.”

“Peel strength” is a value of 180-degree peel strength as measured by pulling a protective film on the upper side and a protective film on the lower side of a 25 mm-width specimen at a rate of 300 mm/min.

“Unintentional separation” shows the state of separation of the protective films A, A1, and A2 stacked on the transparent PET side after the completion of the etching.

For the protective films A, A1, and A2, “separability” shows, for example, the level of force necessary for manually stripping the protective film after the confirmation of the “unintentional separation.” For the protective films B, B1, and B2, “separability” shows the level of force evaluated by cutting the sample into the size of 700 mm×900 mm covering the size area of 600 mm×800 mm of the above mesh pattern and then confirming, for example, the state of the protective film and the level of force necessary for manually stripping the protective film.

TABLE 1

| | Transparent PET side | | | | | |
|---|---|---|---|---|---|---|
| | | | Unintentional | | Copper mesh side | |
| | Peel strength | | separation | Separability | Peel strength | Separability |
| Ex. 1 | 83 | mN | None | Good | — | — |

| | | | | | | |
|---|---|---|---|---|---|---|
| Ex. 2 | — | — | — | 15 | mN | Good |

| | | | | | | |
|---|---|---|---|---|---|---|
| Comp. | 6 | N | None | High peel force | — | — |
| Ex. 1 | | | | required and | | |
| | | | | breaking occurred | | |
| Comp. | 2 | mN | Separated | Lifting occurred | — | — |
| Ex. 2 | | | NG | | | |

| | | | | | | |
|---|---|---|---|---|---|---|
| Comp. | — | — | — | 5.3 | N | High peel force |
| Ex. 3 | | | | | | required and |
| | | | | | | breaking occurred |
| Comp. | — | — | — | 1 | mN | Lifting occurred |
| Ex. 4 | | | | | | |

1. A sheet for electromagnetic wave shielding, comprising a laminate of at least a transparent substrate film and an electromagnetic wave shielding layer,
said electromagnetic wave shielding layer being formed of a meshy metal foil with densely arranged openings and being transparent,
a protective film being stacked separably on the laminate either in its surface of transparent substrate film side or in its surface of electromagnetic wave shielding layer side.

2. A sheet for electromagnetic wave shielding, comprising a laminate of at least a transparent substrate film and an electromagnetic wave shielding layer,
said electromagnetic wave shielding layer being formed of a meshy metal foil with densely arranged openings and being transparent,
a protective film being stacked separably on the laminate both in its surface of transparent substrate film side and in its surface of electromagnetic wave shielding layer side.

3. The sheet according to claim 1, wherein the peel strength between the protective film and the laminate is 5 mN/25 mm-width to 5 N/25 mm-width.

4. The sheet according to claim 1, for use in an electromagnetic wave shielding panel.
